(19) United States
(12) Patent Application Publication
(10) Pub. No.: US 2024/0191348 A1
(43) Pub. Date: Jun. 13, 2024

(54) SEMICONDUCTOR MANUFACTURING APPARATUS AND CLEANING METHOD OF SEMICONDUCTOR MANUFACTURING APPARATUS

(71) Applicant: Hitachi High-Tech Corporation, Minato-ku, Tokyo (JP)

(72) Inventors: Masaki YAMADA, Tokyo (JP); Aki TAKEI, Tokyo (JP); Yosuke KUROSAKI, Tokyo (JP); Takashi HATTORI, Tokyo (JP)

(21) Appl. No.: 17/908,798

(22) PCT Filed: Jul. 19, 2021
(86) PCT No.: PCT/JP2021/026923

§ 371 Date: Sep. 1, 2022

(51) Int. Cl. C23C 16/44; C23C 16/40; C23C 16/52; H01L 21/311; H01L 21/67

(52) U.S. Cl. CPC C23C 16/4405; C23C 16/402; C23C 16/52; H01L 21/31116; H01L 21/67069; H01L 21/67115

(57) ABSTRACT

An object of the invention is to provide a technique that can decrease a reaction product or residual HF in a chamber. A semiconductor manufacturing apparatus includes an inlet to introduce a processing gas containing vapor of hydrogen fluoride and vapor of alcohol into a processing room in a processing container, a sample stage disposed in the processing room and having an upper surface on which a wafer to be processed is placed, and an introduction mechanism to introduce a polar molecular gas to the inlet.

### TECHNICAL FIELD

The present invention relates to a semiconductor manufacturing apparatus that processes a film to be processed disposed on a substrate-like sample such as a semiconductor wafer to manufacture a semiconductor device, and a cleaning method of the semiconductor manufacturing apparatus.

### BACKGROUND ART

In semiconductor-device manufacturing including a process of forming a circuit structure by processing a film to be processed beforehand formed on a sample such as a semiconductor wafer, there is an increasing demand for more accurate processing technique with size reduction of the semiconductor device. Specifically, a SiO₂ film including silicon oxide (SiO₂) is used for various semiconductor-device circuits, and a technique for etching the SiO₂ film has been continuously investigated and progressed. As recent processing of the SiO₂ film, so-called vapor etching, in which vapor of a particular substance is supplied as a processing gas to a surface of the SiO₂ film to react atoms or molecules of the substance with SiO₂ without plasma, is progressively developed. Although wet etching using hydrofluoric acid has been mainly used as a method for removing the SiO₂ film in the past, a problem such as device pattern collapse due to surface tension is now noticeable with recent size reduction of the semiconductor device. Vapor etching using a mixed gas of hydrogen fluoride (HF) and alcohol is therefore proposed as described in NPTL 1, NPTL 2, or PTL 1, for example. Further, a low-temperature process at −10° C. or lower has recently shown promise to increase etching selectivity of SiO₂ to silicon nitride (SiN) in the vapor etching using HF and alcohol.

### CITATION LIST

### Patent Literature

PTL 1: Japanese Unexamined Patent Application Publication No. 2005-161493.

### Nonpatent Literature

NPTL 1: Chun Su Lee et al., “Modeling and Characterization of Gas-Phase Etching of Thermal Oxide and TEOS Oxide Using Anhydrous HF and CH₃OH”, J. Electrochem. Soc., vol. 143, No. 3, pp. 1099-1103 (1996).
NPTL 2: Keiichi Shimaoka et al., “Characteristic of Silicon Nitride Reaction to Vapor-Phase HF Gas Treatment”, IEEJ Trans. SM, vol. 26, No. 9, pp. 516-521 (2006).

### SUMMARY OF INVENTION

### Technical Problem

A cleaning method of the inside of a chamber (reaction chamber) of a vacuum container is one challenge of a semiconductor manufacturing apparatus (referred to as non-plasma dry processing apparatus for convenience) to achieve vapor etching. Although an existing dry etching apparatus can clean the inside of the chamber with plasma (such as oxidizing/physical energy-assisted plasma), the non-plasma dry processing apparatus having no plasma source is less likely to perform previous cleaning of the inside of the chamber with plasma. In the low-temperature process using HF, device characteristics of a semiconductor device formed on a semiconductor wafer are noticeably deteriorated due to influence of fluorine caused by a reaction product generated during etching.

FIG. 1 is a schematic view of vapor etching of a stacked structure 33 of SiN films 31 and SiO₂ films 32. A mixed gas 34 of hydrogen fluoride HF and methanol CH₃OH (shown as ALC in FIG. 1) is used as etching gas for vapor etching. Etching of the SiO₂ film 32 proceeds according to reaction formula 1 (NPTL 1).

SiO₂+4HF+2CH₃OH→SiF₄(↑)+2H₂O+2CH₃OH Reaction Formula 1

In this process, surplus HF adheres as residual gas to the stacked film 33 of SiN and SiO₂. The quantity of adhered HF tends to increase with a decrease in temperature, and the quantity of the residual hydrogen fluoride 35 (shown by open circles in FIG. 1) increases in the low-temperature process using the mixed gas 34 of HF and CH₃OH as described in PTL 2. Ammonium fluorosilicate ((NH₄)₂SiF₆) being an alteration product is known to be generated on the SiN film 31 in etching using the vapor gas of HF and CH₃OH (NPTL 2). Although ammonium fluorosilicate is normally a substance that sublimates by heating, when a so-called cold spot at a sublimation temperature or lower exists in the inside of a chamber, ammonium fluorosilicate as a reaction product 36 deposits in the chamber in some case. FIG. 1 shows the reaction product 36 by open triangles Δ.

Although there is a possible method, in which ammonium fluorosilicate deposited on the semiconductor wafer or in the chamber is sublimated by heating with an infrared (IR) lamp or hot gas, many portions in the chamber are not directly irradiated with infrared light emitted by the IR lamp. For example, the lower side of a stage (sample stage), on which the semiconductor wafer is placed and processed, is not directly irradiated with infrared light emitted by the IR lamp, and the reaction product or the residual HF is problematically deposited thereon. The residual fluorine is difficult to be decreased only by the IR lamp.

In light of maintenance of the semiconductor manufacturing apparatus, when the chamber is opened to the atmosphere, HF remaining in the chamber becomes hydrofluoric acid that has a profound effect on a human body. Hence, cycle purge must be carefully performed before the chamber is opened to the atmosphere, and thus time of the cycle purge accounts for a large percentage of downtime, causing a reduction in maintainability.

An object of the invention is to provide a technique that can decrease the reaction product or the residual HF in the chamber.

### Solution to Problem

A typical embodiment of the invention is briefly summarized as follows.

A semiconductor manufacturing apparatus according to one embodiment includes an inlet to introduce a processing gas containing vapor of hydrogen fluoride and vapor of alcohol into a processing room in a processing container, a sample stage disposed in the processing room and having an upper surface on which a semiconductor wafer to be processed is placed, and an introduction mechanism to introduce a polar molecular gas to the inlet.

### Advantageous Effects of Invention

The semiconductor manufacturing apparatus according to the one embodiment provides an effect of decreasing a reaction product or residual HF in a chamber (reaction chamber). Hydrogen fluoride remaining in the chamber may concernedly vary the etching rate of SiO₂ or affect device characteristics of a semiconductor device. Hence, a decrease in such a reaction product or residual HF makes it possible to prevent a variation in etching rate between individual semiconductor wafers or deterioration in device characteristics of the semiconductor device. As a result, it is possible to improve a yield of etching processing in etching of a film including SiO₂.

### BRIEF DESCRIPTION OF DRAWINGS

FIG. 1 is a schematic diagram illustrating adhesion of a residue to a stacked film of SiN and SiO₂ using HF and methanol.

FIG. 2 is a schematic diagram illustrating adhesion of a residue in an etching chamber.

FIG. 3 is a cross-sectional view of a semiconductor manufacturing apparatus having a first oxide film-removing etching chamber including a cleaning mechanism according to an embodiment.

FIG. 4 is a cross-sectional view of a semiconductor manufacturing apparatus having a second oxide film-removing etching chamber including a cleaning mechanism according to the embodiment.

FIG. 5 is a cross-sectional view of a semiconductor manufacturing apparatus having a third oxide film-removing etching chamber including a cleaning mechanism according to the embodiment.

FIG. 6 is an overall block diagram of the semiconductor manufacturing apparatus having the first oxide film-removing etching chamber of FIG. 3.

FIG. 7 is an overall block diagram of the semiconductor manufacturing apparatus having the second oxide film-removing etching chamber of FIG. 4.

FIG. 8A is a process flow diagram in the case where a constant CH₃OH gas is made to flow with constant output of a second infrared lamp in a cleaning process.

FIG. 8B is a process flow diagram when CH₃OH is introduced pulsatively in the cleaning process.

FIG. 8C is a process flow diagram when output of the second infrared lamp is pulsatively applied in the cleaning process.

FIG. 9A is a flowchart illustrating gas flowrate in case of no cleaning process after etching.

FIG. 9B illustrates temporal transition of residual hydrogen fluoride in case of no cleaning process after etching.

FIG. 10A is a flowchart illustrating gas flowrate when CH₃OH gas is made to flow after etching.

FIG. 10B illustrates temporal transition of residual hydrogen fluoride when CH₃OH gas is made to flow after etching.

FIG. 11A is a flowchart illustrating gas flowrate when heated CH₃OH gas is made to flow after etching.

FIG. 11B illustrates temporal transition of residual hydrogen fluoride when heated CH₃OH gas is made to flow after etching.

FIG. 12A is a flowchart illustrating gas flowrate when heated N₂ gas is made to flow after etching.

FIG. 12B illustrates temporal transition of residual hydrogen fluoride when heated N₂ gas is made to flow after etching.

### DESCRIPTION OF EMBODIMENT

One embodiment of the invention is now described with drawings. In the following description, corresponding components are designated by corresponding reference numerals or signs, and duplicated description may be omitted. Although the drawings may be schematically shown compared with an actual aspect to more clarify the description, such an aspect is merely an example and should not restrict interpretation of the invention.

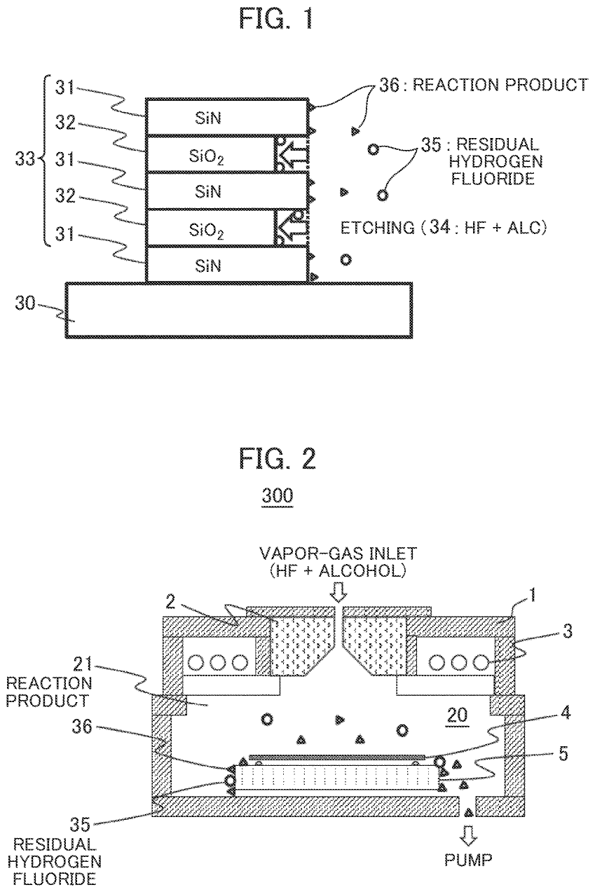

FIG. 1 is a schematic diagram illustrating adhesion of a residue to a stacked film of SiN and SiO₂ using HF and methanol. In an etching process of the SiO₂ film 32 using the mixed gas 34 of hydrogen fluoride HF and methanol CH₃OH as an etching gas, surplus hydrogen fluoride as shown in FIG. 1 remains in a form of the residual hydrogen fluoride 35 in a chamber (reaction chamber) of a semiconductor manufacturing apparatus. The reaction product 36 typified by ammonium fluorosilicate is formed on the SiN film 31, and may remain in the chamber when being heated to be removed, for example. When the above-described low-temperature etching is performed, such residual hydrogen fluoride 35 or reaction product 36 tends to adhere to the stacked film 33 of the SiN film 31 and the SiO₂ film 32 formed on a semiconductor wafer (semiconductor substrate) 30 to be processed.

FIG. 2 is a schematic diagram illustrating generation and adhesion of a reaction product in an etching chamber to achieve etching of an oxide film using HF and alcohol. A semiconductor manufacturing apparatus 300 includes a vacuum container 1, a gas introduction part 2, a first infrared lamp 3, a semiconductor wafer 4 to be etched, and a low-temperature stage 5 being temperature-controlled by a chiller or the like. In FIG. 2, 36 represents the reaction product typified by ammonium fluorosilicate, and 35 represents residual hydrogen fluoride. The low-temperature stage 5 is a sample stage having an upper surface on which the semiconductor wafer 4 to be processed is placed. The vacuum container 1 configures an etching chamber (chamber) 21 internally having a processing room 20 having the sample stage 5 on which the semiconductor wafer 4 to be processed is disposed.

To obtain an etching selectivity of SiO₂ to SiN, temperature of the low-temperature stage 5 is characteristically maintained at a temperature of −20° C. or lower, for example. The first infrared lamp 3 characteristically heats part of the wafer 4 or the low-temperature stage 5 through power control. The above-described residual hydrogen fluoride 35 or reaction product 36 easily adheres not only to the wafer 4 but also to other parts within the chamber 21 in the low-temperature process. Although the vacuum container 1 is designed to suppress adhesion of such a substance to a wall material by heater heating or the like, the residual hydrogen fluoride 35 or the reaction product 36 tends to adhere to a place that is not heated by the infrared lamp 3, such as, for example, a side surface or a lower portion of the low-temperature stage 5. Such an adhered residual hydrogen fluoride 35 or reaction product 36 causes deterioration of device characteristics of a semiconductor device formed on the semiconductor wafer 4, or reduction in maintenance properties of the semiconductor manufacturing apparatus 300 including the vacuum container 1.

The invention therefore provides a method for decreasing the residual hydrogen fluoride 35 or the reaction product 36 by using a heated polar molecular gas as a cleaning gas after etching. A hydrogen fluoride molecule is known to be a so-called polar molecule that is electrically polarized due to a strong electronegativity of fluorine. Thus, electrochemical elimination using a polar molecule, including, for example, an alcohol having an alkyl group or water, is desirable to efficiently remove the residual hydrogen fluoride 35 adhered to the inside of the chamber 21. Since the low-temperature etching intended by the invention increases adhesion coefficient as described above, high-temperature gas irradiation is desirable for elimination of the residual hydrogen fluoride 35. For these reasons, it is probably possible to remove the residual hydrogen fluoride 35 by the heated polar molecular gas.

The invention further provides a chamber cleaning method using a heated polar molecular gas as a method for removing a fluorinated compound, such as residual hydrogen fluoride HF or ammonium fluorosilicate, adhered to a region in the chamber (reaction chamber) that cannot be directly heated by infrared light emitted by an infrared (IR) lamp. The polar molecular gas can be heated using a method of heater heating, IR lamp heating, or addition of the polar molecular gas to hot gas. HF is a gas having polarity due to a hydrogen bond, and is characteristically easily mixed with a polar molecular gas such as an alcohol gas. Specifically, since alcohol has large infrared absorption in an infrared wavelength range, gas can be efficiently heated at a molecular level by IR heating with an IR lamp. It is therefore possible to efficiently remove residual fluorine by alcohol heated by IR heating even in a region that is not directly irradiated with infrared light emitted from the IR lamp.

This leads to an effect of decreasing the reaction product or the residual HF in the chamber (reaction chamber). Hydrogen fluoride remaining in the chamber may concernedly vary the etching rate of SiO₂ or affect device characteristics of a semiconductor device. Hence, a decrease in such a reaction product or residual HF makes it possible to prevent a variation in etching rate between semiconductor wafers or deterioration in device characteristics of the semiconductor device.

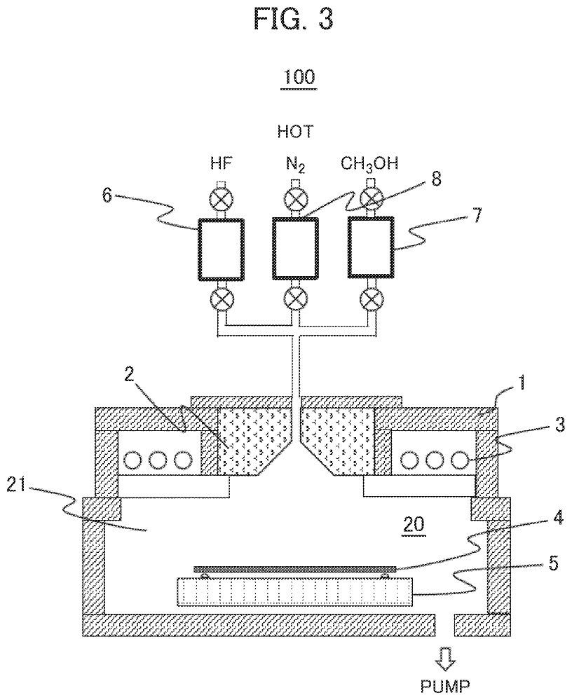

FIG. 3 is a cross-sectional view of a semiconductor manufacturing apparatus having a first oxide film-removing etching chamber to achieve the invention. As described with FIG. 2, a semiconductor manufacturing apparatus 100 includes a vacuum container (processing container) 1, a gas introduction part (inlet) 2, a first infrared lamp 3, a semiconductor wafer 4 to be etched, and a low-temperature stage 5 being temperature-controlled by a chiller or the like. The low-temperature stage 5 is a sample stage having an upper surface on which the semiconductor wafer 4 to be etched is placed. The vacuum container 1 configures an etching chamber (chamber) 21 internally having a processing room 20 having the sample stage 5 on which the semiconductor wafer 4 to be processed is disposed. The gas introduction part 2 is to introduce a processing gas containing vapor of hydrogen fluoride HF and vapor of alcohol (HF and polar molecular gas) into the processing room 20.

The semiconductor manufacturing apparatus 100 further includes a HF regulator 6, a regulator 7 for a polar gas containing a hydroxy group (OH group), and a regulator 8 for a beforehand heated gas. The polar-gas regulator 7 serves as an introduction mechanism to introduce a polar molecular gas to the gas introduction part 2.

The polar gas containing an OH group generally refers to an alcohol (abbreviated as ALC), such as methanol CH₃OH, ethyl alcohol C₂H₅OH, or propanol C₃H₇OH, and water H₂O. In the invention, however, the polar gas includes any form of a polar molecular gas, which has a molecular structure including an OH group and has a biased electrical polarity.

For the heated-gas regulator 8, a gas that does not directly contribute to etching of SiO₂, such as argon Ar, helium He, and nitrogen N₂, is desirable as the heated gas. FIG. 3 exemplarily shows heated nitrogen N₂. The invention does not limit a method for heating the gas.

In a method for removing the SiO₂ film using the first oxide film-removing etching chamber 21, the SiO₂ film is etched using the HF regulator 6 and the polar-molecular-gas regulator 7 such that a flowrate ratio of the HF to the polar molecular gas is appropriate for the etching.

For a cleaning process of the inside of the first oxide film-removing etching chamber 21, the polar-gas regulator 7 and the heated-gas regulator 8 are used to mix the polar molecular gas with the heated gas to substantially heat the polar molecular gas. The first infrared lamp 3 may be operated during the cleaning process. Such mechanisms (7, 8) make it possible to remove the residual hydrogen fluoride 35 by the heated polar molecular gas.

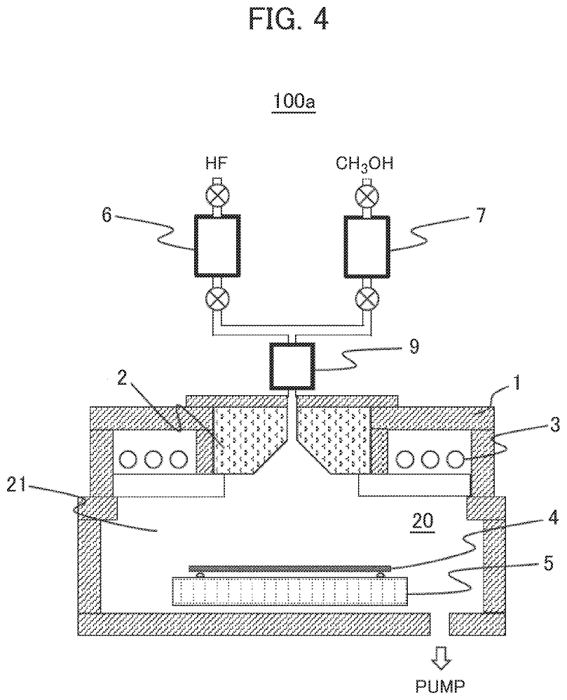

FIG. 4 is a cross-sectional view of a semiconductor manufacturing apparatus having a second oxide film-removing etching chamber to achieve the invention. As described with FIG. 3, a semiconductor manufacturing apparatus 100a includes a vacuum container 1, a gas introduction part 2, a first infrared lamp 3, a semiconductor wafer 4, a low-temperature stage 5, a HF regulator 6, a regulator 7 for a polar gas containing a hydroxy group (OH group), a processing room 20, and an etching chamber (chamber) 21. The semiconductor manufacturing apparatus 100a further includes a gas heating mechanism 9. The gas heating mechanism 9 refers to a mechanism that heats a pipe by a heater, for example. Installation location of the heating mechanism is not limited herein.

In an etching process of the SiO₂ film using the second oxide film-removing etching chamber 21, the SiO₂ film is etched using the HF regulator 6 and the polar-molecular-gas regulator 7 such that a flowrate ratio of the HF to the polar molecular gas (herein, methanol CH₃OH gas) is appropriate for the etching. At this time, while the gas heating mechanism 9 is not operated, a process gas is supplied at a temperature optimum for the etching.

In a process of cleaning the inside of the second oxide film-removing etching chamber 21, while supply of HF is stopped by the HF regulator 6, only the polar molecular gas is supplied by the polar-molecular-gas regulator 7. At this time, the gas heating mechanism 9 is operated to heat the polar molecular gas to a temperature higher than room temperature. As with FIG. 3, the first infrared lamp 3 may be operated during the cleaning process.

Such a gas heating mechanism 9 (and the first infrared lamp 3) makes it possible to remove the residual hydrogen fluoride 35 by the polar molecular gas heated to a temperature higher than room temperature.

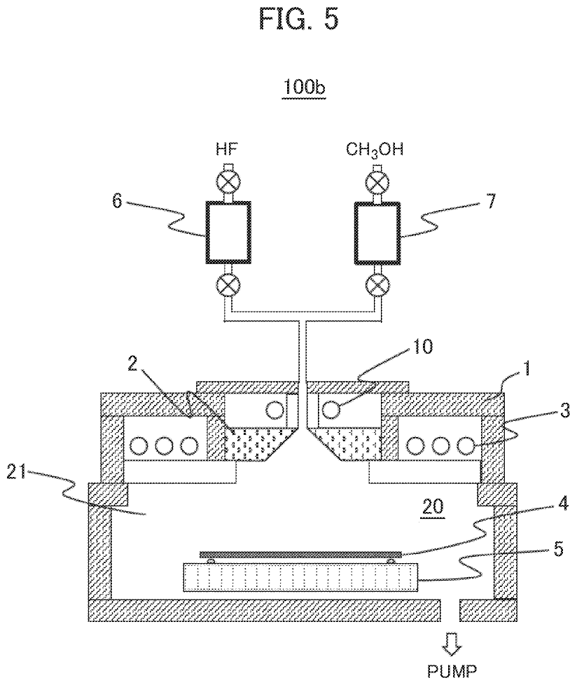

FIG. 5 is a cross-sectional view of a semiconductor manufacturing apparatus having a third oxide film-removing etching chamber to achieve the invention. As described with FIG. 3, a semiconductor manufacturing apparatus 100b includes a vacuum container 1, a gas introduction part 2, a first infrared lamp 3, a semiconductor wafer 4, a low-temperature stage 5, a HF regulator 6, a regulator 7 for a polar gas containing a hydroxy group (OH group), a processing room 20, and an etching chamber (chamber) 21. The semiconductor manufacturing apparatus 100b further includes a second infrared lamp 10. The second infrared lamp 10 is provided to heat by infrared irradiation the polar molecular gas adjusted in flowrate by the polar-gas regulator 7 and desirably placed in the gas introduction part 2 in the vacuum container 1, for example.

In an etching process of the SiO₂ film using the third oxide film-removing etching chamber 21, as with FIG. 4, the SiO₂ film is etched using the HF regulator 6 and the polar-molecular-gas regulator 7 such that a flowrate ratio of the HF to the polar molecular gas (herein, methanol CH₃OH gas) is appropriate for the etching. At this time, heating by the second infrared lamp 10 is not performed. The wafer 4 may be heated by the first infrared lamp 3 depending on a process. A near-infrared wavelength range of 3 μm or less is desirably used for the first infrared lamp 3 to increase heating rate.

In a process of cleaning the inside of the third oxide film-removing etching chamber 21, as with FIG. 4, while supply of HF is stopped by the HF regulator 6, only the polar molecular gas is supplied by the polar-molecular-gas regulator 7. In this cleaning process, the polar molecular gas is heated by the second infrared lamp 10 to a temperature higher than room temperature. For a wavelength range of the second infrared lamp 10, when CH₃OH is exemplarily used as a cleaning gas, a near to middle-infrared wavelength range of approximately 1 to 3 μm is desirably used depending on a type of the polar molecular gas. The middle-infrared rays in such a wavelength band is largely absorbed by a CH₃OH molecule, causing molecule stretching vibration of a C—O or C—H bond in the CH₃OH molecule. As a result, CH₃OH molecules can be efficiently heated by infrared rays. As described above, the first infrared lamp 3 may be operated during the cleaning process.

Such a second infrared lamp 10 (and the first infrared lamp 3) makes it possible to decrease the residual hydrogen fluoride 35 by the heated polar molecular gas.

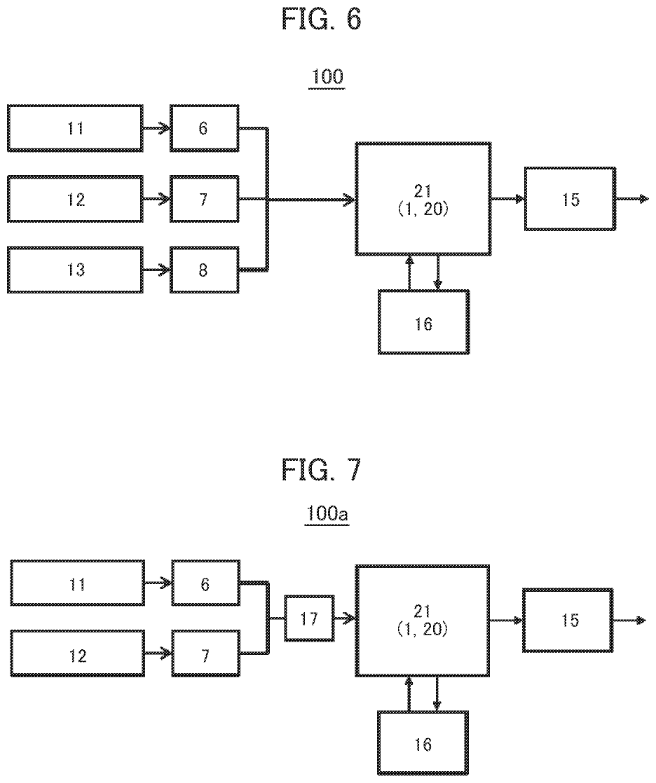

FIG. 6 is an overall block diagram of a semiconductor manufacturing apparatus having the first oxide film-removing etching chamber of FIG. 3. The semiconductor manufacturing apparatus 100 includes the first oxide film-removing etching chamber 21 as described with FIG. 3, the HF regulator 6, the regulator 7 for a polar gas containing a hydroxy group (OH group), the regulator 8 for a beforehand heated gas, a HF supplier 11, an alcohol supplier 12, a supplier 13 of a carrier gas other than HF and alcohol, an evacuation device 15, and a chiller 16.

The HF supplier 11 enables supply of HF gas using, for example, a high-pressure cylinder, and supplies the HF gas to the etching chamber 21 through the HF regulator 6.

The alcohol supplier 12 heats a liquid alcohol stored in a canister or the like to vaporize the alcohol, and supplies such alcohol vapor to the etching chamber 21 through the alcohol regulator 7.

The supplier 13 of a carrier gas other than HF and alcohol represents a high-pressure cylinder of a less reactive carrier gas such as Ar, He, and N₂, for example. The carrier gas is beforehand heated by a heater or the like before being supplied into the chamber 21 through the hot-gas regulator 8.

The evacuation device 15 is configured of, for example, a dry pump or a turbo molecular pump, and exhausts gas and reaction products from the inside of the etching chamber 21.

The chiller 16 can control temperature of the low-temperature stage 5 in the etching chamber 21.

FIG. 7 is a block diagram of a semiconductor manufacturing apparatus having the second oxide film-removing etching chamber of FIG. 4. The semiconductor manufacturing apparatus 100a includes the oxide film-removing etching chamber 21 described with FIG. 4, the HF regulator 6, the regulator 7 for a polar gas containing a hydroxy group (OH group), the HF supplier 11, the alcohol supplier 12, the evacuation device 15, the chiller 16, and a pipe heating mechanism 17. The HF supplier 11, the alcohol supplier 12, the evacuation device 15, and the chiller 16 each have a configuration as described with FIG. 6.

The pipe heating mechanism 17 is configured to be able to heat a pipe extending from the gas regulator 7 to the gas introduction part 2 for the etching chamber 21. The pipe heating mechanism 17 can heat the polar molecular gas to a temperature higher than room temperature. Although heater heating is generally used as a heating method, the invention does not specify a heating form.

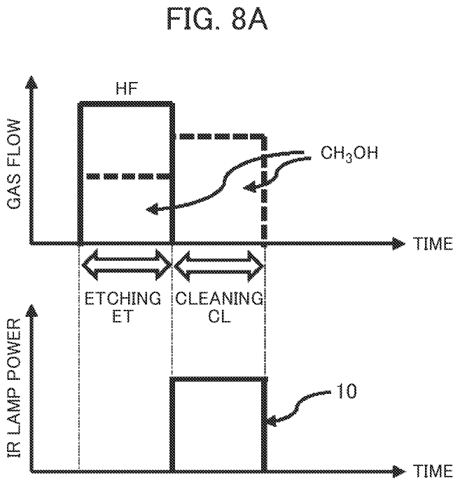

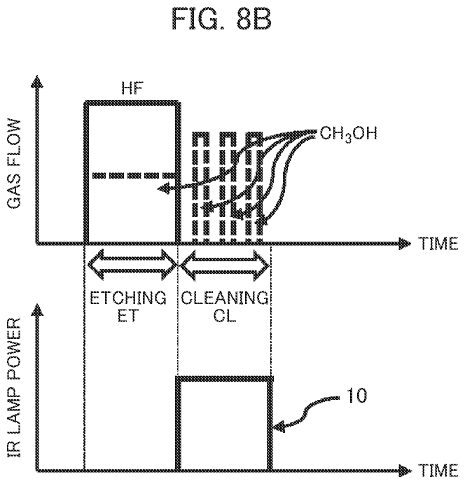

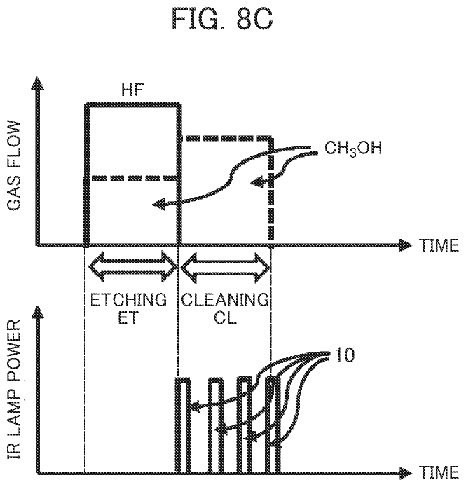

FIGS. 8A to 8C are each a process flow diagram of a residue cleaning process CL. Description is now given on an example where a mixed gas of HF and CH₃OH is used as an etching gas, and CH₃OH is used as a cleaning gas. Description is further given on an exemplary case using the semiconductor manufacturing apparatus 100b having the third oxide film-removing etching chamber as described with FIG. 5.

FIG. 8A illustrates a process flow of a cleaning process CL with a constant CH₃OH gas flow and a constant output of the second infrared lamp 10. HF and CH₃OH are mixed while a flowrate ratio therebetween is adjusted to 2:1 during an etching process ET. The invention does not limit each flowrate. In the cleaning process CL, supply of HF is zero, and flowrate of CH₃OH is higher than in the etching process ET. Although higher flowrate of CH₃OH increases a cleaning effect, the flowrate is desirably controlled to the lower explosion limit or less. Output of the second infrared lamp 10 is constant in the cleaning process CL. Since the magnitude of the output greatly depends on performance of the second infrared lamp 10, an appropriate output value is desirably used such that CH₃OH is efficiently heated. Hence, the maximum flowrate of the cleaning gas and the output value of the infrared lamp 10 are each not specified in the invention.

FIG. 8B illustrates a process flow when CH₃OH is introduced pulsatively in the cleaning process CL. FIG. 8B shows an exemplary case where CH₃OH is pulsatively supplied multiple times (herein, three times) into the etching chamber 21 in the cleaning process CL.

FIG. 8C illustrates a process flow when output of the second infrared lamp 10 is pulsatively applied in the cleaning process CL. FIG. 8C shows an exemplary case where the second infrared lamp 10 is pulsatively turned on multiple times (herein, three times) to heat the inside of the etching chamber 21 in the cleaning process CL.

The cleaning method of the semiconductor manufacturing apparatus is summarized as follows.

The cleaning method of the semiconductor manufacturing apparatus includes, for example, the following. In the semiconductor manufacturing apparatus 100b as illustrated in FIG. 5,
(1) placing the wafer 4 on the sample stage 5 in the processing room 20,
(2) etching process: in the processing room 20, etching the silicon oxide film 32 formed on the wafer 4 with the mixed gas containing vapor of hydrogen fluoride and vapor of the polar molecular gas, and
(3) cleaning process: subsequently, introducing alcohol (CH₃OH), the flowrate of which is higher than the flowrate of alcohol (CH₃OH) during the etching of the silicon oxide film 32, into the processing room 20 (see FIGS. 8A to 8C), and introducing the polar molecular gas (CH₃OH), which is irradiated with infrared rays by the heating mechanism (second infrared lamp 10), into the processing room 20 and thus cleaning the inside of the processing room 20. As a result, residual hydrogen fluoride HF is removed from the inside of the processing room 20.

In the invention, a process flow including a plurality of sets of the cleaning processes CL of FIGS. 8A to 8C is also within the scope of the invention.

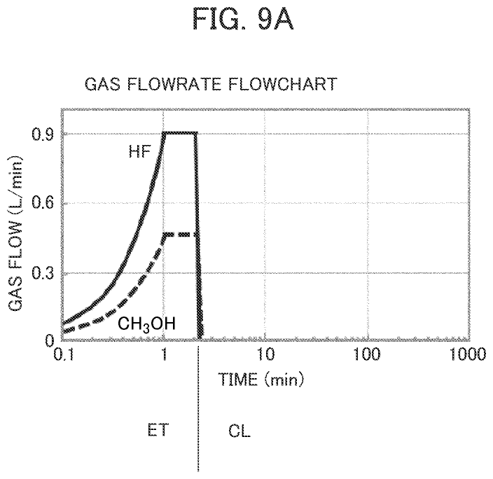

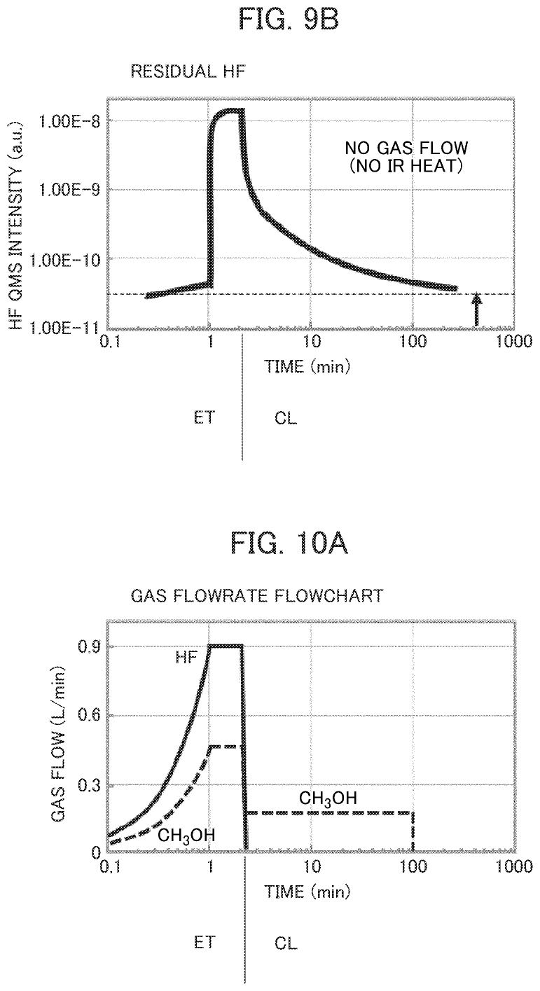

Experimental results are now described with FIGS. 9A to 12B.

FIGS. 9A to 12B illustrate results of temporal transition of residual hydrogen fluoride HF in a plurality of exemplary cases of the same etching condition of the etching process ET but different cleaning conditions of the cleaning process CL in the case using the semiconductor manufacturing apparatus having the third oxide film-removing etching chamber as illustrated in FIG. 5.

FIGS. 9A and 9B each illustrate a case of no cleaning process CL (a cleaning condition of no CH₃OH gas flow and no infrared heating). FIG. 9A is a flowchart illustrating gas flowrate, and FIG. 9B illustrates temporal transition of the residual hydrogen fluoride HF.

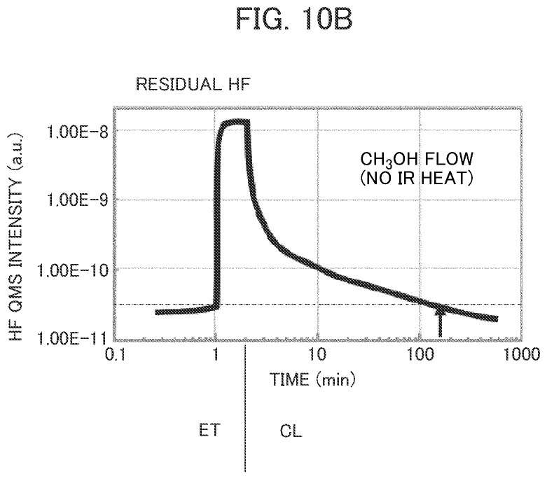

FIGS. 10A and 10B each illustrate a case of a cleaning condition where only the CH₃OH gas is made to flow without infrared heating in the cleaning process CL. FIG. 10A is a flowchart illustrating gas flowrate, and FIG. 10B illustrates temporal transition of the residual hydrogen fluoride HF.

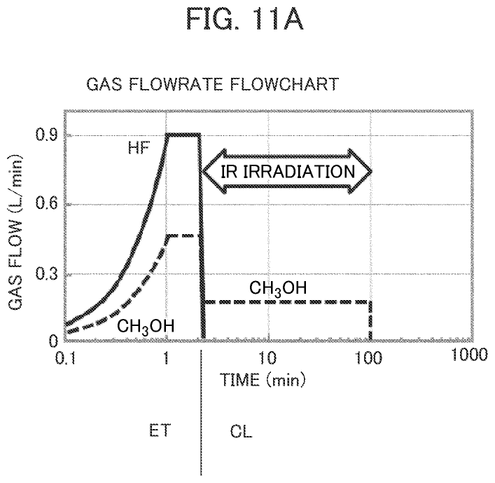

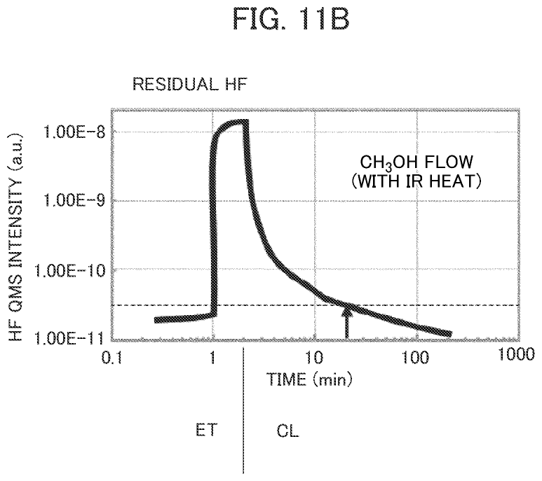

FIGS. 11A and 11B each illustrate a case of a cleaning condition where CH₃OH gas is heated by the infrared lamp 10 in the cleaning process CL. FIG. 11A is a flowchart illustrating gas flowrate, and FIG. 11B illustrates temporal transition of the residual hydrogen fluoride HF.

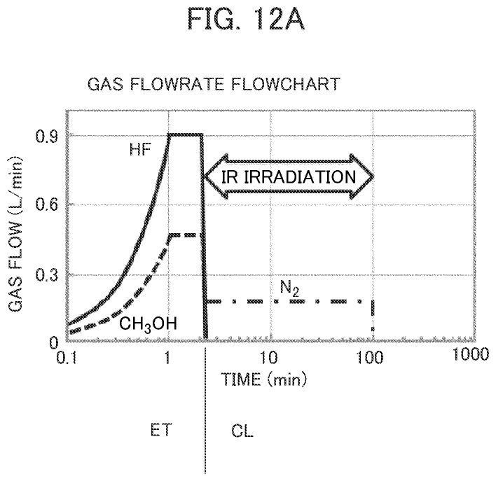

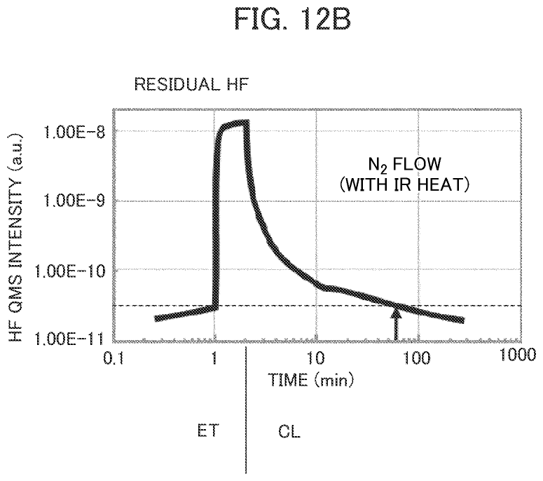

FIGS. 12A and 12B each illustrate a case of a cleaning condition where nitrogen N₂ gas is used in place of the CH₃OH gas and heated by the infrared lamp 10 in the cleaning process CL. FIG. 12A is a flowchart illustrating gas flowrate, and FIG. 12B illustrates temporal transition of the residual hydrogen fluoride HF.

In this exemplary case, the SiO₂ film 32 (see FIG. 1) is etched using the mixed gas of HF and CH₃OH as an etching gas in the etching process ET, and the amount of the residual hydrogen fluoride HF after the etching process ET is measured using a quadruple mass spectrometer (Q-mass) in order to measure the amount of the residual hydrogen fluoride HF after the etching process ET in the third oxide film-removing etching chamber 21. The flowrate of the mixed gas used for etching of the SiO₂ film 32 includes 0.9 (L/min) for HF and 0.45 (L/min) for CH₃OH. In the etching process ET, etching temperature is −20° C. and etching time is 1 min.

FIG. 9B illustrates a result of temporal transition of the amount of the residual hydrogen fluoride in an aftertreatment process for removing the residual hydrogen fluoride HF under the cleaning condition (see FIG. 9A) of no supply of the cleaning gas (CH₃OH gas) and no irradiation of the infrared lamp 10. The evacuation device 15 starts evacuation of the chamber 21 two minutes after the SiO₂ film 32 has been completely etched. Such evacuation decreases the amount of the residual hydrogen fluoride HF. Assuming that Q-mass intensity of 3.0×10⁻¹¹ (counts) is the threshold of the amount of the residual hydrogen fluoride for convenience, the amount has not decreased to 3.0×10⁻¹¹ (counts) or less only by the evacuation even after the lapse of five hours or more.

FIG. 10B illustrates a result of the amount of the residual hydrogen fluoride in case of the cleaning condition (see FIG. 10A) where methanol CH₃OH gas is made to flow as the cleaning gas without heating by the infrared lamp 10. The methanol introduced as the cleaning gas is made to flow for 100 min at a flowrate of CH₃OH of 0.15 (L/min). The result shows that Q-mass intensity of the residual hydrogen fluoride decreases to 3.0×10⁻¹¹ (counts) in approximately 150 min by flowing CH₃OH even without heating by the infrared lamp 10. The result thus reveals that exhaust time of the residual hydrogen fluoride can be reduced by using methanol CH₃OH as the cleaning gas.

FIG. 11B illustrates a result of the amount of the residual hydrogen fluoride in case of the cleaning condition (see FIG. 11A) where methanol CH₃OH gas is made to flow as the cleaning gas with heating by the infrared lamp 10. The flowrate condition of the cleaning gas is the same as the condition (flowrate of CH₃OH of 0.15 (L/min)) of flow of the methanol CH₃OH gas in FIG. 10A, and the methanol CH₃OH gas is heated by the infrared lamp 10 during flow of the gas. Time required to reach the threshold 3.0×10⁻¹¹ (counts) is short, approximately 20 min, by heating the methanol CH₃OH gas by the infrared lamp 10. This result (FIG. 11B) thus reveals the effect of reducing the cleaning time to 94, or less compared with a case where the inside of the chamber 21 is not cleaned (FIGS. 9A and 9B). The result further reveals the effect of reducing the cleaning time approximately 87% compared with the cleaning condition (FIGS. 10A and 10B) where nonheated methanol CH₃OH gas is made to flow.

For comparison, investigation is also made on a cleaning effect in case using nitrogen N₂ gas being a nonpolar molecular gas. FIG. 12B illustrates results of the investigation. The flowrate of the nitrogen N₂ gas is 0.15 (L/min), and the gas is heated for 100 min by the infrared lamp 10. Cleaning time of the residual hydrogen fluoride HF (time required to reach the threshold 3.0×10⁻¹¹ (counts)) of 60 min is given by flow of the heated nitrogen N₂ gas. This reveals that the cleaning time for the heated nitrogen N₂ gas is approximately three times longer than the cleaning time (20 min) for the heated methanol CH₃OH gas.

As known from the above results, polar molecular gas is more efficiently heated by the infrared lamp 10 than nonpolar molecular gas, and residual hydrogen fluoride can be effectively cleaned by IR heating of the polar molecular gas according to the invention.

Although the invention achieved by the inventors has been specifically described according to examples, the invention should not be limited to the above embodiment and examples, and it will be appreciated that various modifications or alterations may be made.

### LIST OF REFERENCE SIGNS

1 vacuum container (processing container)
2 gas introduction part
3 first infrared lamp
4 wafer
5 low-temperature stage (sample stage)
6 HF regulator
7 polar molecular gas regulator
8 hot gas regulator
9 heating mechanism
10 second infrared lamp
11 HF supplier
12 polar molecular gas supplier
13 hot gas supplier
15 evacuation device
16 chiller
17 pipe heating mechanism
20 processing room
21 etching chamber (chamber)
100, 100a, 100b semiconductor manufacturing apparatus

1. A semiconductor manufacturing apparatus, comprising:
an inlet to introduce a processing gas containing vapor of hydrogen fluoride and vapor of alcohol into a processing room in a processing container;
a sample stage disposed in the processing room and having an upper surface on which a wafer to be processed is placed; and
an introduction mechanism to introduce a polar molecular gas to the inlet.

2. The semiconductor manufacturing apparatus according to claim 1, wherein the polar molecular gas includes an alcohol having an alkyl group or water.

3. The semiconductor manufacturing apparatus according to claim 2, further comprising a heating mechanism that heats the polar molecular gas to a temperature higher than room temperature.

4. The semiconductor manufacturing apparatus according to claim 3, wherein the heating mechanism is provided between the inlet and the introduction mechanism.

5. The semiconductor manufacturing apparatus according to claim 3, wherein the heating mechanism is a heating mechanism using infrared irradiation and is provided at the inlet.

6. A cleaning method of a semiconductor manufacturing apparatus, the method comprising:
placing the wafer on the sample stage in the processing room of the semiconductor manufacturing apparatus according to claim 5;
in the processing room, etching silicon oxide on the wafer with a mixed gas containing vapor of hydrogen fluoride and vapor of a polar molecular gas; and
subsequently, introducing alcohol into the processing room, the alcohol having a flowrate equal to or higher than flowrate of alcohol during the etching of the silicon oxide, and introducing the polar molecular gas into the processing room, the polar molecular gas being subjected to the infrared irradiation by the heating mechanism, and thus cleaning the inside of the processing room.
